(19) United States
(12) Patent Application Publication
(10) Pub. No.: US 2007/0069398 A1
(43) Pub. Date: Mar. 29, 2007

(54) Overlay metrology mark

(76) Inventors: Nigel Peter Smith, Hsinchu (TW); Michael J. Hammond, York (GB)

Correspondence Address: PERKINS COIE LLP;PATENT-SEA, P.O. BOX 1247, SEATTLE, WA, 98111-1247, US

(21) Appl. No.: 10/549,863

(22) PCT Filed: Apr. 8, 2004
(86) PCT No.: PCT/GB04/01533

§ 371 Date: Dec. 8, 2006

(30) Foreign Application Priority Data
Apr. 8, 2003 (GB) 0308082.7
Apr. 8, 2003 (GB) 0308086.8

(51) Int. Cl. H01L 23/48; H01L 29/40; H01L 21/00; H01L 23/544; H01L 23/52

(52) U.S. Cl. 257/797; 257/734; 438/797

(57) ABSTRACT

An overlay metrology mark for determining the relative position between two or more layers of an integrated circuit structure comprising a first mark portion associated with and in particular developed on a first layer and a second mark portion associated with and in particular developed on the surface of a second layer, wherein each mark portion comprises a single two dimensional generally orthogonal array of individual test structures. A method of marking and a method of determining overlay error are also described.

The invention relates to overlay metrology during semiconductor device fabrication, and in particular to an overlay alignment mark to facilitate alignment and/or measure the alignment error of two layers on an integrated circuit structure during its fabrication.

Modern semiconductor devices, such as integrated circuits, are typically fabricated from wafers of semiconductor material. In particular, a wafer is fabricated comprising a succession of patterned layers of semiconductor material.

Circuit patterns are fabricated using a variety of long established techniques, for example making use of lithographic techniques. Precise positioning and alignment during fabrication is of great significance in the manufacture of accurate patterns. For example, alignment control of the exposure tool is important in ensuring a consistent process. Alignment methodologies are established in this regard, in which statistical and modelling techniques are used to determine the alignment of a reticle with a pattern created by or in association with the exposure tool to facilitate alignment of the exposure tool. The technique typically exploits images generated within the exposure tool optics, or projected onto the wafer by the exposure tool optics. Similar model-based and statistical methods have been employed to align for example an exposure tool during pattern fabrication.

Although such alignment technology has an established utility, and is important in device fabrication, it relates to alignment of fabrication tooling only. This can be a limitation in relation to semiconductor structures comprised of a succession of pattern layers of semiconductor material where it is desirable in relation to such wafers to provide a methodology enabling a determination of the misregistration between fabricated layers themselves.

Overlay metrology in semiconductor device fabrication is used to determine how well one printed layer is overlaid on a previously printed layer. Close alignment of each layer at all points within the device is crucial for reaching the design goals and hence the required quality and performance of the manufactured device. It is consequently of importance for the efficiency of the manufacturing process that any alignment error between two patterned layers on a wafer, especially successive patterned layers can be measured quickly and accurately. It is similarly important to be able to measure any alignment error between successive exposures in the same layer, and where reference is made herein for convenience to two layers it will be understood where appropriate to apply equally to two exposures in the same layer.

Misregistration between layers is referred to as overlay error. Overlay metrology tools are used to measure the overlay error. This information may be fed into a closed loop system to correct the overlay error.

Current overlay metrology employs optically readable target patterns, printed onto the successive layers of a semiconductor wafer during fabrication. The relative displacement of two successive layers is measured by imaging the patterns at high magnification, digitizing the images, and processing the image data using various known image analysis algorithms to quantify the overlay error. Overlay metrology techniques thus involve the direct measurement of misregistration between patterns provided in direct association with each of the fabricated layers under investigation. In particular, patterns are developed in or on the surface of each of the layers, or may be latent images, rather than images generated within or projected from the optics of an imaging instrument.

The pattern of the target mark may be applied to the wafer by any suitable method. In particular, it is often preferred that the mark is printed onto the wafer layers for example using photolithographic methods. Typically, the same technique is used to apply overlay target marks on each of two wafer layers to be tested to enable alignment information to be measured which is representative of the alignment of the layers. Accuracy of layer alignment should correspond to accuracy of circuit pattern alignment within the fabricated wafer.

Current overlay metrology is normally practised by printing targets with rectangular symmetry. For each measurement two targets are printed, one in the current layer and one in a previous layer, or one in association with each pattern in a common layer. The choice of which previous layer to use is determined by process tolerances. The two targets have a nominally common centre, but are printed with different sizes so that they can be differentiated. Normally, but not always, the target printed in the current layer is the smaller of the two targets. An overlay measurement in such a system is the actual measured displacement of the centres of the two targets.

Current preferred practice is that the size of the targets is designed such that both can be imaged simultaneously by a bright-field microscope. Imaging considerations determine that the larger of the two targets is typically a 25 μm square on the outside. This arrangement permits capture of all of the necessary data for the performance of the measurement from a single image. Measurements at a rate of one in every two seconds or less are possible using current technology.

The procedure necessarily requires that the target and its image are symmetric, since otherwise there is no uniquely defined centre point. Without symmetry there is an uncertainty in the measurement, which may be more than can be tolerated. Within that general requirement, optimal sizes and shapes of current designs of targets to be measured are well known. The targets are positioned in the scribe area at the edge of the fabricated circuit.

It is generally desirable that the measurement targets maintain axial symmetry about the optical axis of the measurement tool, since accurate measurement requires very close control of image aberrations. To achieve this it can also therefore be advantageous to use marks at or with symmetry centred about the system axis.

Marks exhibiting symmetry are usually aligned in a known and consistent relationship relative to the crystal lattice of the wafer. Where this defines “X” and “Y” directions these are conveniently used as reference directions for the imaging apparatus. The “X” and “Y” planes are more specifically relevant to the wafer than they are to the optics, but it is normal to choose to align the wafer such that “X” corresponds to the horizontal and “Y” to the vertical as viewed through the microscope. It is possible in principle to measure at any other orientation, but for many mark symmetries advantages are conferred if the marks are arranged to have symmetry about what are conventionally termed the “X” and the “Y” axes, which allows the optimum performance to be obtained from the metrology apparatus.

In most prior art systems, measurements are therefore made from the targets by computing a centre line for each different target. The overlay measurement is the difference in the centre lines. Most of the target designs in general use permit measurement of the vertical and horizontal overlay displacement from a single image.

Measurement errors must be controlled to a very small amount. Errors known to arise are classified as random errors, characterized by determination of measurement precision; and systematic errors, characterized by tool induced errors, tool-to-tool measurement differences and errors introduced by asymmetry in the targets being measured. Successful application of overlay metrology to semiconductor process control is generally held to require that, combined, these errors are less than 10% of the process control budget. This measurement error budget is in practice in the range 1 to 5 nm, and will remain so in the foreseeable future.

Measurement precision is easily determined by analysis of the variations of repeated measurements. Different forms of precision may be determined by well known appropriate methods, allowing determination of the static, short-term and long-term components of precision.

Determining the contribution of the measurement tool alone to errors is achieved by comparing measurements made with the target in its normal presentation with a measurement made after rotating the target by 180° with respect to the imaging system. Ideally the measurement will simply change sign. The average of the measurements at 0° and 180° is called Tool Induced Shift (TIS), as is well known to those skilled in the art, and is widely accepted as a measure of the tool's systematic error contribution. Measurements of TIS differ from tool to tool and with process layer. Subtraction of the estimated TIS error from the measurements allows removal of the TIS error from the measurements, but at the expense of the additional time taken to measure the target twice.

Different tools, even when of the same type, will make slightly different measurements, even after allowing for precision and TIS errors. The magnitude of this error can be determined experimentally by comparing the averages of repeated measurements at 0° and 180° on two or more tools.

The contributions of precision, TIS and tool-to-tool differences are normally combined through a root-sum-square product, or alternative appropriate method, to determine the total measurement uncertainty due to the measurement process. The total measurement uncertainty must be less than 10% of the overall overlay budget for the process if the metrology is to have value. Existing measurement tools and procedures achieve a total uncertainty within that required for current process technologies but insufficient for future requirements.

By contrast, although the contribution of asymmetry in the measurement target itself is widely understood it is not normally determined. It is known that in many cases it can be much larger than the tool contribution to measurement uncertainty. There are two sources of error to be considered:
1. Imperfection in the manufacture of the target which leads to an uncertainty in its location. An example of this is physical asymmetry of the target, caused perhaps by uneven deposition of a metal film.
2. Difference in the displacement of the two layers at the measurement target and the genuine overlay of the same layers in the device being manufactured. These can arise from errors in the design and manufacture of the reticles used to create the patterns on the wafer, proximity effects in the printing process and distortion of the films after printing by other process steps.

These measurement errors represent a practical limitation of the current state of the art which causes severe problems in the application of overlay metrology to semiconductor process control.

Improvements to the first of these problems can sometimes be achieved by fabricating the features in the measured targets from much smaller objects—lines or holes. The common term for this technique is “segmentation”. These smaller features are printed at the design rule for the process, currently in the range 0.1-0.2 μm, and are grouped close together. They are too small to be individually resolved by the optical microscopes used in overlay metrology tools. The small features are grouped into larger shapes in the pattern of traditional overlay targets. The use of small features avoids some of the mechanisms causing imperfections in the shape of the manufactured targets, in part by taking advantage of the optimization of the manufacturing process for objects of this size and shape.

A further problem is introduced by the size of the targets, which are a significant fraction of the space available in the scribe area surrounding the devices being fabricated. It is desired that the size of these areas be reduced, which means that it is also highly desirable that the measurement targets be made smaller. However, the size of the target cannot be reduced too much, since accurate measurement requires that the measured features are not smaller than the resolution of the microscope system, and achieving good precision requires that as many as possible of such features are visible in the image.

It has been shown (Smith, Nigel P.; Goelzer, Gary R.; Hanna, Michael; Troccolo, Patrick M., “Minimizing overlay measurement errors”, August 1993, Proceedings of SPIE Volume: 1926 Integrated Circuit Metrology, Inspection, and Process Control VII, Editor(s): Postek, Michael T) that space must be left between the features printed from the two layers else the proximity of one to another causes an error in the measurement. The magnitude of this error depends on the resolution of the imaging microscope system, but must be 5 μm or greater in practical designs if the measurement error is to be contained within practical limits. This proximity effect further limits the extent to which the size of the targets can be reduced.

However, high speed is one of the key advantages of existing overlay metrology practice, and any process development must not lose this advantage if it is to be viable in production use. This requirement means that uncertainty reduction by the use of repeated measurements is highly undesirable. There is thus a general desire to develop alternative overlay patterns and/or analysis methods which apply the basic principles of existing metrologies but in a manner that mitigates some or all of these errors to produce an improved fabrication metrology, and in particular a metrology offering improved accuracy without substantial loss of throughput speed.

In accordance with the present invention in a first aspect an overlay metrology mark for determining the relative position between two or more layers of an integrated circuit structure comprises a first mark portion associated with a first layer and a second mark portion associated with a second layer, wherein each mark portion comprises a single two dimensional generally orthogonal, and preferably generally square, array of individual test structures.

It should be emphasised that a mark in accordance with the invention is an overlay metrology mark, in which a mark portion is directly associated with each of the first and second layer to provide a directly measurably indication of the misregistration or overlay error between the layers under investigation. In particular, each mark portion is preferably developed in or on the surface of the wafer layer in such direct association. For example, each mark portion may be printed onto the wafer layer, for example using the same technique which is used to apply the circuit pattern, and for example using photolithographic methods. Alternatively, a mark may be a latent image. The two mark portions, comprising the complete overlay metrology mark, are imaged together to obtain a quantification of any overlay error.

The invention discloses novel target designs that address the disadvantages of the existing technology, in particular offering significantly improved accuracy, without sacrificing advantages in relation to speed of processing and otherwise.

The invention exploits the realisation that effective information about alignment in two directions may be given by a single square array exploiting entirely conventional imaging techniques, such as the bright field techniques commonplace in the prior art. Scanning this pattern in two dimensions, more specifically orthogonal X-Y scanning parallel to the two linear directions of the array, yields information about misalignment in both directions. This offers the potential to yield an overlay error measurement representative of layer misalignment in two dimensions from a single marked region using standard or specifically developed image analysis techniques to determine the misregistration between the two patterns. More complex patterns involving two or more regions in each mark, each adapted to measure misalignment in a particular direction, are not necessary, provided a single accurately disposed array of individual test structures in accordance with the invention is laid down upon each layer, or associated with each pattern, as the case may be.

A further advantage is that existing metrology tools may be simply adapted to their measurement, avoiding the costs involved in retooling that radically different methods would require.

Each mark portion is associated with a layer under test, so that the measured overlay error is representative of the misalignment between the respective layers. Overlay metrology marks in accordance with the invention are suited to measurement of overlay errors between layers, in particular but not limited to consecutive layers. Where the overlay mark is used to aid measurement of misregistration between different layers, the first mark portion is laid down upon a first lower layer, and the second mark portion is laid down upon a second layer above the said first layer, in particular on an uppermost layer, such that the test structures of the lower layer are detectable through the upper layer. The upper mark portion serves as an alignment marking, and the lower mark portion as the reference marking.

The test structures comprising each mark portion are disposed in each case as a single two dimensional array with an orthogonal arrangement. This should be understood to mean that each array comprises an arrangement of individual test structures forming a plurality of parallel rows and columns, the row and column directions being at right angles to each other. In use these should correspond to the mirror angles of the optical equipment used for image analysis. The structures form a repeating array. For most applications a substantially square array, with generally constant spacing between test structures throughout the array, will be preferred. In certain cases, a functionally varying spacing between adjacent rows and/or columns respectively in a column/row direction as the case may be useful for particular functionality, provided always that the orthogonal relationship of rows and columns is maintained.

Preferably the spacing between test structures in the array comprising the first mark portion and the spacing between test structures in the array comprising the second mark portion is equivalent. In particular both are square arrays of generally equal spacing.

The overall mark portion preferably also has a generally square outline. It is desirable if asymmetries are to be avoided. However minor deviations in particular are unlikely to be significant. Moreover, the requirement for an orthogonal array of successive rows and columns does not preclude designs where individual test structures are absent from a limited portion of the sites defined thereby. Such gaps might be incorporated for example to add readable information, or to include further mark features giving such give additional information. Such gaps/additional marks are preferably located so as to maintain symmetry of the structure in the mark portion and/or about the intended optic axis of the imaging apparatus.

The dimensions of each test structure within each array and the spacing thereof will be optimally determined by and are therefore preferably set with reference to the resolution limit of the imaging microscope. Typically therefore each test structure will have a width of around 0.5 to 2 μm. Spacing between test structures in the array will preferably be between one and four structure widths. This will maximise feature density at the resolution limit of the imaging device. Any specific design embodying the principles of the invention will increase the number of feature transitions when compared with many previous designs. Each array may comprise several test structures in each direction, preferably at least five, while fitting comfortably into a conventional mark area. The additional image detail provides more information content in the image, providing for an improvement in measurement precision.

The individual test structures making up each array are preferably substantially identically sized and shaped. Each test structure conveniently has generally square geometry.

Individual test structures may optionally be made using design rule sized sub-structures to address issues of process induced inaccuracy, as is well known.

Suitable arrangements, familiar to those skilled in the art, include parallel arrays of elongate rectangular sub-structures in either direction, arrays of square sub-structures, circles in square or hexagonal array, arrays of holes within a suitably shaped test structure and any combinations of these or other like patterns. Sub-structure dimensions are set by design rule limits, being typically for present techniques of the order of 100 to several hundreds of nanometres. However advances in manufacturing processes are likely to further reduce these dimensions in the future.

In use with a standard imaging device, the orthogonal arrays making up each mark portion are to be aligned with the vertical and horizontal grid directions of each array (ie the rows and columns formed by the test structures) parallel to each other and to the X-Y symmetry lines of the imaging device. It has been noted that optimal performance depends on measurement being centred on the optic axis of the imaging device. Two embodiments are proposed to facilitate this.

In a first embodiment the arrays of test structures making up the first and second mark portions are disposed such that the first portion overlays the second portion and that the test structures at least to some extent are intercalated, especially in both directions. That is, the test structures of the second portion are arrayed within the gaps between the test structures of the first portion and visible therebetween. In particular, each test structure in the second portion is located at a point sitting at or in close proximity to the diagonal centre of a notional square bounded at each corner by test structures of the first portion.

The mark in accordance with the invention is an overlay metrology mark, and it follows that the two mark portions are imaged together to measure the overlay error between the two layers under test, with the intercalated structures of the lower layer visible in the gaps between the structures of the upper layer. The geometry of this embodiment thus lends itself particularly to an overlay metrology, and the patent gives a particularly effective method of measuring overlay error in two dimensions.

Preferably, the two test portions are laid down with generally co-located centres, the common centre intended to correspond to the optic axis of the imaging system in use, but it will be understood that minor asymmetry in this regard, especially at the edges of the structure will not seriously degrade measurement accuracy as long as the interlaced arrangements is maintained.

In this embodiment, the design is optimised if test structures in each array are spaced with a pitch of around three to four times the width of an individual test structure. This provides adequate gaps in the array comprising the upper mark portion for visibility of test structures in the lower mark portion therethrough.

In a second embodiment the test structures making up the first and second mark portions are disposed such that the first portion is laterally spaced from the second portion in a spacing direction parallel to a horizontal or vertical direction of the square arrays such that a notional line in the spacing direction can be drawn about which each array exhibits mirror symmetry. In use this will correspond to one of the mirror axes of the imaging device, with the centre point of this notional line equidistant from each mark portion intended to correspond to the optic axis of the imaging system. Each mark portion will preferably comprise an identical pattern of test structure.

In this second embodiment arrays, and preferably square arrays, making up the first and second mark portions are laid down so as to be generally adjacent with the centroid of the combined mark preferably generally at the optic axis of the imaging device. Again, this effectively exploits the overlay metrology technique to measure overlay error between the two layers with which the mark portions are associated, and in particular allows measurement in two dimensions even if only a single mark portion is provided in association with each layer.

In this embodiment, the design is optimised if test structures in each array are spaced with a repeat distance, and in particular a constant periodicity, of two to three structure widths, in particular around two, i.e. so that the spacing between test structures is the same as the width of an individual structure.

In both of the foregoing principal embodiments, the overlay metrology mark comprised of the first and second mark portions is preferably so located in use that the centroid of the overall mark corresponds generally to the optic axis of the imaging apparatus. Other patterns which also conform to this general principal are also likely to be preferred as embodiments of the present invention.

The test structures making up the array comprising each mark portion may be laid down by any suitable technique known to those skilled in the art, in particular the photolithographic techniques above described.

In a preferred embodiment a recognition key is provided for use in association with an overlay mark as hereinbefore described. In accordance with the embodiment an identification portion is provided in association with a first mark portion, comprising a simple optically readable mark divided into a small number of pattern areas in each of which areas a marking may be present or absent, the pattern of such markings providing a unique identification key so as to serve to identify the first mark portion.

An identification portion in accordance with the invention is associated with the alignment mark and gives a simple digital identification of the alignment mark, ensuring the correct mark is selected. The identification portion thus acts as a pattern recognition key.

A similar identification portion may be associated with other marks on a wafer, whereby the embodiment of the invention comprises an overlay metrology mark system for the whole wafer ensuring the correct marks are selected at all times. The probability of locating the wrong overlay metrology mark can be reduced by varying the pattern in adjacent marks, increasing the distance to a potentially confusing pattern recognition key.

In particular, the identification portion is laid down with the first mark portion, for example at the same time and for example on the same layer. The identification portion is conveniently located proximal to the first mark portion, for example comprising a part thereof.

The recognition key comprises a simple pattern exhibiting a small number of discrete alternative shapes to give a digital identifier. The pattern is adapted to be optically readable by standard imaging equipment at the same time as the primary alignment mark is imaged, requiring no major equipment modification and only minimal modification to image analysis. The recognition key is preferably laid down by the same process as the primary mark, for example employing photolithographic techniques. However, the pattern making up the recognition key is designed to be optically imaged for recognition purposes only, and not for determination of alignment differences. The structure can accordingly be made from structural element(s) which optimise this aspect, and might therefore be substantially larger than the structures making up the primary alignment mark.

The recognition key pattern comprises a small number of pattern areas, for example between four and eight, in each of which areas a marking may be present or absent, the pattern of such markings thus providing the unique identification. In particular, in each pattern area a marking is either substantially entirely present or substantially entirely absent. The arrangement of which pattern areas are present and which are absent gives the unique key. For example, for simplicity it might be preferable if a mark is absent in a single pattern area.

Preferably, the recognition key pattern has a generally square or rectangular outline. This is particularly the case where the corresponding primary mark has generally square or rectangular symmetry. In particular, the horizontal and vertical directions of such a square or rectangular outline correspond to the horizontal and vertical directions of a similarly square or rectangular overlay mark, and in use with the x and y directions of symmetry in the optical imaging apparatus. As a consequence of this geometry, each pattern area is similarly preferably square or rectangular. The recognition key pattern then preferably comprises a linear or two-dimensional array of such pattern areas, for example consisting of between one and four such areas in each of a row and column direction, corresponding in use to the x and y directions in the optical imaging apparatus.

Each pattern area preferably has dimensions of between 1 and 4 μm, and particularly preferably comprises a 1 μm square. All pattern areas making up the recognition key pattern are preferably identically sized and shaped.

In particular, the key pattern comprises a square or rectangular area sub-divided into a two dimensional array of square or rectangular pattern areas. This gives a highly readable identification mark, maintaining the square or rectangular symmetry of many of the alignment marks with which it is intended to be used, and accordingly easily readable by the imagining equipment. Suitable overall pattern dimensions are from 2 to 8 μm, allowing pattern area dimensions of 1 to 2 μm for ease of imaging. In particular pattern areas are 1 to 2 μm squares.

In a particular embodiment the recognition key pattern comprises a square divided into four equal sub-square pattern areas as above described. Each sub-square pattern area is either present or absent in the recognition key pattern. Mostly preferably, the recognition key pattern comprises a generally L-shaped mark, wherein there are four such sub-square pattern areas in one of which a mark absent. The mark provides four distinct patterns (dependent upon the orientation of the L-shape) which are easily readable and distinguished. This is sufficient for many purposes.

It is well known that optimal performance depends on measurement being centred on the optic axis of the imaging device. Overlay marks are usually symmetric about this centre, with the overlay error being the measured displacement of the centres. Conveniently, to avoid introducing asymmetry, the recognition key may be located at the centre. Alternatively, a plurality of recognition keys are provided away from the centre.

The advantages of existing target designs are retained. The measurements are made from a single image so that speed of measurement is not compromised. The measurement is made using an optical image, so that existing imaging tools can be used. Overlay error may be quantified using any suitable known or specifically developed image processing technique.

Thus, in accordance with the present invention in a second aspect a method for providing an overlay metrology mark to determine the relative position between two or more layers of an integrated circuit structure comprises the steps of:

laying down a first mark portion in association with a first layer;

and laying down a second mark portion in association with a second layer;

wherein each mark portion comprises a single two dimensional generally square array of generally evenly spaced individual test structures.

Similarly, in accordance with the present invention in a third aspect a method for determining the relative position between two or more layers of an integrated circuit structure comprises the steps of:

laying down a first mark portion in association with a first layer;

laying down a second mark portion in association with a second layer;

wherein each mark portion comprises a single two dimensional generally square array of generally evenly spaced individual test structures;

optically imaging the two mark portions in a horizontal and vertical array direction;

collecting and digitizing the image;

numerically analysing the digitized data to obtain a quantified measurement of the misalignment of the first and second mark portions.

It is important to emphasise that each mark portion making up the overlay metrology mark is laid down in direct association with the associated layer, and in particular is preferably developed within or on the surface of the said layer. For example each mark portion is printed on the said layer. Each mark portion is preferably laid down by a photolithographic process.

In a preferred embodiment of the method of the invention, the overlay metrology mark incorporates an identification mark serving as a recognition key as hereinbefore described. The method thus comprises, in association with the step of laying down of an alignment mark portion associated with a second layer, and for example contemporaneously therewith,

laying down in association with the said mark portion an identification portion comprising a simple optically readable mark divided into a small number of pattern areas in each of which areas a marking may be present or absent, the pattern of such markings providing a unique identification key so as to serve to identify the alignment mark portion.

Optical imaging of the mark is preferably carried out using imaging microscopy, and for example bright field microscopy. Other preferred features of the methods will be understood by analogy with the foregoing.

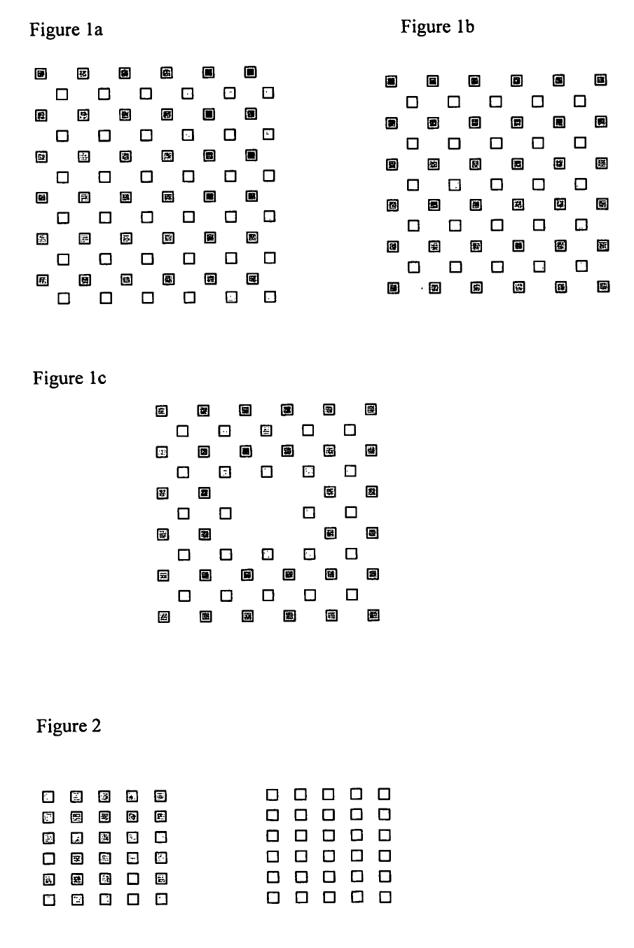

The invention will now be described by way of example only with reference to FIGS. 1 to 2 of the accompanying drawings, in which:

FIGS. 1a to 1c are general schematics of a mark in accordance with a first principal embodiment of the invention comprising superimposed mark portions;

FIG. 2 is a general schematic of a mark in accordance with a second principal embodiment of the invention comprising adjacent mark portions;

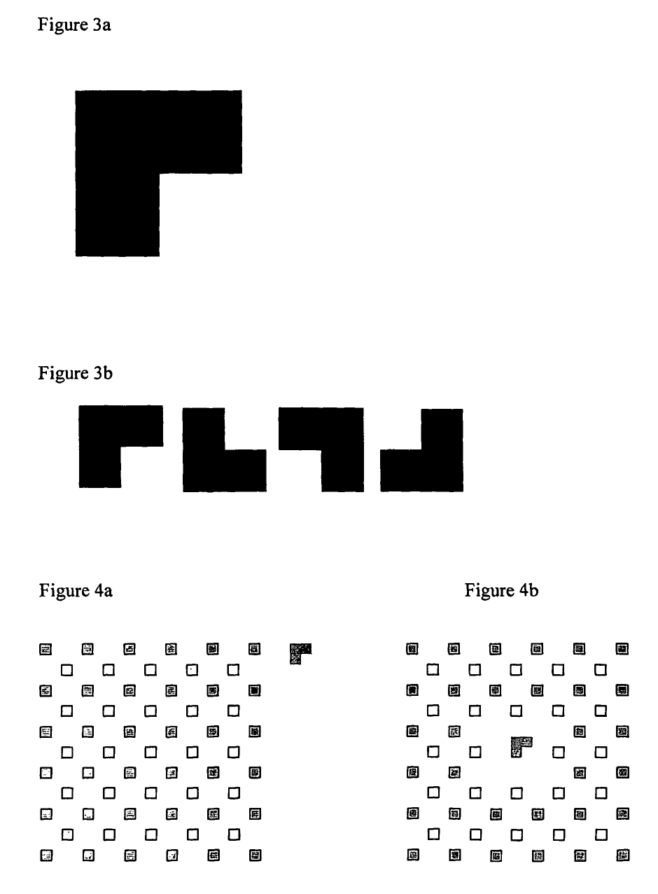

FIG. 3 is a plan view of a suitable identification recognition key for use in accordance with a preferred embodiment of the invention;

FIG. 4 illustrates use of the key of FIG. 3 in association with the marks of FIG. 1;

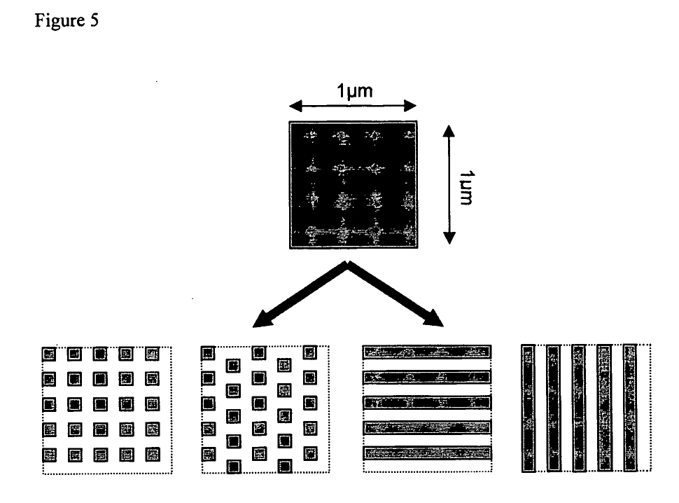

FIG. 5 illustrates example substructures for a mark structure for use with a mark in accordance with the invention.

The overlay metrology mark comprises a first or reference mark portion on a first lower layer and a second or alignment mark portion on a second layer above the first layer, for example an uppermost layer. Where complete marks are illustrated in the figures, the second mark portion is represented by darker grey-shaded structures. The first mark portion, configured to be at least partially visible in conjunction with the second, is represented by lighter grey-shaded structures.

In each case the invention lies in the arrangement of test structures in a repeating array. The structures and any sub-structures making up the test structures are formed using any suitable processes. Typically these will include lithographic processes that are generally known in the art. Misalignment is measured using imaging systems and image analysis techniques, which may be standard systems and techniques that are generally known in the art or systems and techniques modified to be optimized specific to the marks in accordance with the invention.

FIG. 1 illustrates a top plan view of three alternative overlay metrology marks according to one embodiment of the invention. In each case the mark is shown in the intended configuration that results when the tested layers of a structure are in proper alignment. The mark consists of two mark portions, one on each layer, comprising substantially identical square arrays of test structures overlaid into an interlocking pattern, whereby the test structures of the second mark portion lie at the centres of notional squares bounded at the corners by test structures in the first mark portion. Each array also has an overall square shape.

FIG. 1a illustrates the simplest example. Identical square arrays are laid down relatively shifted by half a repeat in both directions to make up the overall structure. This design lacks central symmetry.

FIG. 1b illustrates an arrangement to address this and allow the two arrays to be laid down with a common centroid. The first mark portion is larger by one pattern repeat in both directions, and offset relative to the second by half a pattern repeat in both directions, to maintain rotational symmetry about the common centroids. This common centroid should correspond to the optic axis of the imaging system in use, with mirror axes of the imaging system parallel to the rows and columns of the squares. Given appropriate axis orientation of a suitable imaging device the rows in each array may serve for x-axis registration measurements and the columns for y-axis registration measurements. The simple mark, with a single array comprising the mark portion on a layer, can thus give two dimensional registration information.

Each of the mark portions consists of a square array of repeating test structures. In the examples the period of repeat is constant. Each of the test structures in the example is also square in general outline. Each is shown solid in this plan view, but it will be well understood that it could comprise multiple sub-structures at a design rule level (examples of which are given below) for reasons that will be familiar. In a specific implementation of the example mark each test structure comprises a 1 μm square. Lateral spacing between squares is then around 3 μm to provide the necessary gaps for the interlocking arrangement of the two arrays. Dimensions are set to maximise feature density within a normal mark area and hence accuracy, subject to the resolution limit of a typical imaging system. The measurements will vary in practice, depending on the required accuracy and the resolution limit of the imaging system.

FIG. 1c illustrates an alternative arrangement. Whereas in FIG. 1b the arrays are continuous across the centre, in this arrangement a gap is provided in the centre of the array, into which an identification key mark could be included with the overlay layer to ensure that correct reference and overlay are matched. This is optional, and may limit the effectiveness of the target design due to loss of data.

FIG. 2 illustrates a top plan view of an overlay metrology mark according to a second embodiment of the invention. The mark is shown in the intended configuration that results when the tested layers of a structure are in proper alignment. The mark consists of two mark portions, one on each layer, comprising substantially identical square arrays of test structures. Each array also has an overall square shape.

The two arrays are laid down displaced apart about a notional line which can be drawn parallel to the array rows so as to form a notional mirror symmetry line for each square. The centre of this notional line should correspond to the optic axis of the imaging system in use, with mirror axes of the imaging system parallel to the rows and columns of the squares. As before, with appropriate axis orientation of a suitable imaging device the rows in each array may serve for x-axis registration measurements and the columns for y-axis registration measurements so that the simple mark, with a single array comprising the mark portion on a layer, can give two dimensional registration information.

Each mark portion is preferably laid down by a photolithographic process. As before, each of the test structures in the example is also square in general outline and shown solid but could comprise multiple sub-structures at a design rule level. In a specific implementation of the example mark each test structure comprises a 1 μm square. Lateral spacing between squares is also around 1 μm. Dimensions are again set to maximise feature density subject to the resolution limit of a typical imaging system.

FIG. 3a shows a basic recognition key suitable for use with the overlay metrology mark of the invention in accordance with a preferred embodiment thereof. The mark is shown in top plan view. Increasingly, new measurement structures do not provide an easy pattern recognition target as there is no isolated well-resolved image in the resist. The key comprises a specific mark printed in the resist layer. The mark consists of a 2 μm square mark area subdivided into a two by two array of 1 μm square pattern areas. Three of these are covered by the mark material and one absent. The effect is to produce a key comprising a 2 μm square from which one corner is omitted, giving a general L-shape.

Any corner may be omitted, allowing four unique pattern recognition targets to be created as illustrated in FIG. 3b. The simplicity of the design makes this easy to image, and easy to distinguish between the four targets, so that the key provides a clear digital identifier of a given overlay mark with which it is associated, and greatly assists in ensuring the correct overlay mark is imaged. Overlay targets can be positioned nearby but will be safe from pattern recognition error if the keys are different. The probability of locating the wrong target can be reduced by varying the omitted corner in adjacent targets, increasing the distance to a potentially confusing pattern recognition key.

FIG. 4 illustrates use of the key of FIG. 3 in association with the marks of FIG. 1. In FIG. 4a a key is placed adjacent a mark of the type shown in FIG. 1b. In FIG. 4b a key is placed centrally within a mark of the type shown in FIG. 1c. These examples are illustrative only of the various arrangements that could be envisaged.

FIG. 5 illustrates example substructures for a mark structure for use with a mark in accordance with the invention. A single individual test structure from those making up each array of a mark in accordance with the invention is shown above, being a 1 μm square. Such an individual test structure may optionally be made using design rule sized sub-structures to address issues of process induced inaccuracy, as is well known. In the illustrated four examples below, the 1 μm square comprises patterns of square or rectangular substructures to form the required shape. Because the small features are not resolved, they are not individually visible through the microscope, giving the appearance of a single contiguous structure. The mark-space ratio of the sub-resolution features can be adjusted to meet the optimal performance criteria of the printing process.

1. An overlay metrology mark for determining the relative position between two or more layers of an integrated circuit structure comprising a first mark portion associated with a first layer and a second mark portion associated with a second layer, wherein each mark portion comprises a two dimensional generally orthogonal array of individual test structures.

2. An overlay metrology mark in accordance with claim 1 wherein each mark portion is within or on the said layer.

3. An overlay metrology mark in accordance with claim 2 wherein each mark portion is formed on the said layer by a microlithographic process.

4. An overlay metrology mark in accordance with claim 1 wherein each mark portion comprises a single two dimensional generally substantially square array of individual test structures with generally constant spacing between test structures throughout the array.

5. An overlay metrology mark in accordance with claim 1 wherein the spacing between test structures in the array comprising the first mark portion and the spacing between test structures in the array comprising the second mark portion is equivalent.

6. An overlay metrology mark in accordance with claim 5 wherein each mark portion has a generally square outline.

7. An overlay metrology mark in accordance with claim 1 wherein each test structure has a width of around 0.5 to 2 μm.

8. An overlay metrology mark in accordance with claim 1 wherein spacing between test structures in the array is between one and four times a widths of the test structures.

9. An overlay metrology mark in accordance with claim 1 wherein individual test structures of an array have substantially identically sizes and shapes and are generally square.

10. An overlay metrology mark in accordance with claim 1 wherein individual test structures comprise arrangements of design rule sized sub-structures.

11. An overlay metrology mark in accordance with claim 10 wherein the arrangements of design rule sized sub-structures are at least one of parallel arrays of elongate rectangular sub-structures in either direction, arrays of square sub-structures, circles in square or hexagonal array, arrays of holes within a suitably shaped test structure and any combinations of these or other like patterns.

12. An overlay metrology mark in accordance with claim 10 wherein sub-structures have design rule dimensions.

13. An overlay metrology mark in accordance with claims 1 wherein the arrays of test structures making up the first and second mark portions are disposed such that the first portion overlays the second portion and that the test structures of second portion are arrayed within the gaps between the test structures of the first portion and visible therebetween.

14. An overlay metrology mark in accordance with claim 13 wherein individual test structures in the second portion are located at the diagonal centre of a square bounded at each corner by test structures of the first portion.

15. An overlay metrology mark in accordance with claim 1 wherein the test structures making up the first and second mark portions are disposed such that the first portion is laterally spaced from the second portion in a spacing direction parallel to a horizontal or vertical direction of the square arrays such that a notional line in the spacing direction can be drawn about which each array exhibits mirror symmetry.

16. An overlay metrology mark in accordance with claim 15 wherein each mark portion comprises an identical pattern of test structures.

17. A method for providing an overlay metrology mark to determine the relative position between two or more layers of an integrated circuit structure comprises the steps of:
laying down a first mark portion in association with a first layer;
and laying down a second mark portion in association with a second layer;
wherein each mark portion comprises a single two dimensional generally square array of generally evenly spaced individual test structures.

18. A method for determining the relative position between two or more layers of an integrated circuit structure comprises the steps of:
laying down a first mark portion in association with a first layer;
laying down a second mark portion in association with a second layer;
wherein each mark portion comprises a single two dimensional generally square array of generally evenly spaced individual test structures;
optically imaging the two mark portions;
collecting and digitizing the image;
numerically analysing the digitized data to obtain a quantified measurement of the misalignment of the first and second mark portions.

19. The method of claim 18 wherein optical imaging of the mark is carried out using bright field microscopy.

20. The method of claim 17 wherein individual mark portions are developed within or on the layer.

21. The method of one of claim 17 wherein individual mark portions are formed by a microlithographic process.

22. (canceled)

23. The method of claim 18 wherein individual mark portions are developed within or on the layer.

24. The method of claim 18 wherein individual mark portions are formed by a microlithographic process.
